(19) United States
(12) Patent Application Publication
(10) Pub. No.: US 2016/0143150 A1
(43) Pub. Date: May 19, 2016

(54) METHOD OF MANUFACTURING A FLEXIBLE PRINTED CIRCUIT BOARD INCLUDING A SOLDER RESIST LAYER

(71) Applicant: KABUSHIKI KAISHA TOSHIBA, Tokyo (JP)

(72) Inventors: Akihiko HAPPOYA, Ome Tokyo (JP); Kota TOKUDA, Kawasaki Kanagawa (JP)

(21) Appl. No.: 14/842,283

(22) Filed: Sep. 1, 2015

(30) Foreign Application Priority Data
Nov. 14, 2014 (JP) 2014-231564

(51) Int. Cl. H05K 3/00; B41J 2/01

(52) U.S. Cl. CPC H05K 3/007; B41J 2/01

(57) ABSTRACT

A method for manufacturing a flexible printed circuit module includes discharging an insulating material from an inkjet head towards a surface of a flexible printed circuit board, such that an electrode on the surface of the flexible printed circuit board is exposed, and curing the insulating material to be formed.

### CROSS-REFERENCE TO RELATED APPLICATION

This application is based upon and claims the benefit of priority from Japanese Patent Application No. 2014-231564, filed Nov. 14, 2014, the entire contents of which are incorporated herein by reference.

### FIELD

Embodiments described herein relate to a method of manufacturing a printed circuit board including a solder resist layer.

### BACKGROUND

In general, a solder resist layer is formed on a surface of a flexible printed circuit board. Such a solder resist layer is conventionally formed through an application process of an insulating material in a liquid form on the entire surface of a substrate using screen printing or the like, a drying process of the insulating material, and a lithography process of the insulating material. It would be desirable to efficiently form such a solder resist layer.

### DESCRIPTION OF THE DRAWINGS

FIG. 1 is a perspective view of an electronic device including a module manufactured through a method according to a first embodiment.

FIG. 2 is a perspective view of the module included in the electronic device shown in FIG. 1.

FIG. 3 is a cross-sectional view of a printed circuit board included in the module shown in FIG. 2.

FIG. 4 is a cross-sectional view of the printed circuit board showing a method of manufacturing the module shown in FIG. 2.

FIG. 5 is a cross-sectional enlarged view of a detailed portion of a solder resist formed on the printed circuit shown in FIG. 2.

FIGS. 6-8 are each a cross-sectional view of a printed circuit board module manufactured through a method according to a second embodiment. FIG. 9 is a cross-sectional view of a printed circuit board module manufactured through a method according to a third embodiment.

FIG. 10 is a cross-sectional view of a printed circuit board module manufactured through a method according to a fourth embodiment.

FIG. 11 is a cross-sectional view of a printed circuit board module manufactured through a method according to a fifth embodiment.

FIG. 12 is a cross-sectional view of a printed circuit board module manufactured through a method according to a sixth embodiment.

FIG. 13 is a cross-sectional view of a printed circuit board module manufactured through a method according to one modification of the sixth embodiment.

FIG. 14 is a perspective view of a semiconductor device manufactured through a method according to a seventh embodiment.

### DETAILED DESCRIPTION

One or more embodiments are directed to provide a method of efficiently forming a solder resist layer.

In general, according to an embodiment, a method for manufacturing a flexible printed circuit module includes discharging an insulating material from an inkjet head towards a surface of a flexible printed circuit board, such that an electrode on the surface of the flexible printed circuit board is exposed, and curing the insulating material to be formed.

Hereinafter, embodiments are described with reference to drawings. In the present disclosure, with respect to some structural elements, a plurality of expressions is used. However, these expressions are merely examples, and each of the above-mentioned structural elements may be expressed in other ways. Further, the structural elements which are expressed in a single way may be expressed in plural ways.

The drawings are schematic views, and hence the relationship between thicknesses and planar sizes, a ratio of thicknesses of the respective layers and the like may not be equal to those of a real product. The relationship or the ratio between sizes of the components may differ between drawings.

### First Embodiment

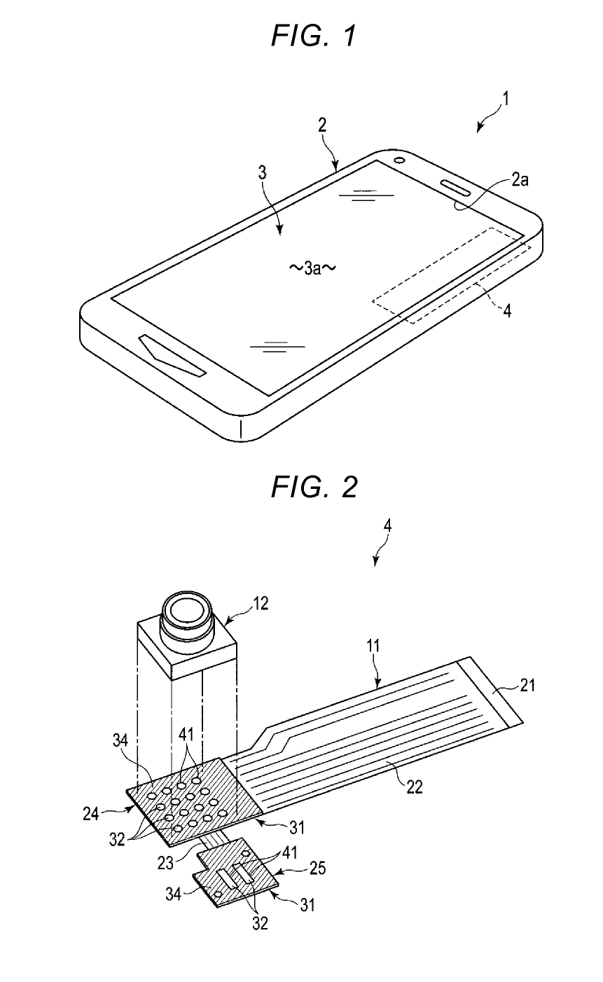

FIG. 1 shows an electronic device 1 according to the first embodiment. The electronic device 1 is, for example, a mobile phone (smart phone). However, the electronic device 1 is not limited to the mobile phone. The electronic device 1 is widely applicable to various electronic devices such as a portable computer, a smart device (e.g., tablet device), an image display device (e.g., a television receiver set) or a game machine. The present embodiment and all other embodiments described hereinafter are not limited to the electronic device 1, and are also applicable to a semiconductor device (a semiconductor component, a semiconductor module) shown in FIG. 14.

As shown in FIG. 1, the electronic device 1 includes a housing 2 (casing), a display device 3 housed in the housing 2, and a module 4 housed in the housing 2. The housing 2 has an opening portion 2a through which a display screen 3a of the display device 3 is exposed. The opening portion 2a is covered by a transparent protection panel (for example, a glass panel or a plastic panel).

FIG. 2 shows the module 4 according to the present embodiment. The module 4 includes a flexible printed circuit board 11 (hereinafter, “printed circuit board 11”) and an electronic component 12 (functional component). The electronic component 12 is mounted on the printed circuit board 11 and electrically connected to the printed circuit board 11.

The module 4 according to the present embodiment is a camera module, for example. Accordingly, one example of the electronic component 12 is a camera. The module 4 is not limited to the above-mentioned example, and various modules may suitably be employed as the module 4. That is, the electronic component 12 mounted on the printed circuit board 11 is not limited to a camera and, broadly, various components may be mounted on the printed circuit board 11 as the module 4.

Next, the printed circuit board 11 is described in detail.

As shown in FIG. 2, one example of the printed circuit board 11 includes a terminal portion 21 (connecting portion), first and second wiring portions 22, 23, and first and second component mounting portions 24, 25. The terminal portion 21 includes a plurality of terminals, and is positioned at an end portion of the printed circuit board 11. The terminal portion 21 is inserted into a connector provided on another substrate or another component, and is electrically connected to the connector. The printed circuit board 11 may include another component mounting portion instead of the terminal portion 21.

The first wiring portion 22 extends between the terminal portion 21 and the first component mounting portion 24 so as to electrically connect the terminal portion 21 and the first component mounting portion 24. The second wiring portion 23 extends between the first component mounting portion 24 and the second component mounting portion 25 so as to electrically connect the first component mounting portion 24 and the second component mounting portion 25. Each one of these wiring portions 22, 23 includes a flexible base film made of polyimide or the like, a wiring pattern formed on the base film, and a cover lay film which covers the wiring pattern. These wiring portions 22, 23 have flexibility.

Each one of the first and second component mounting portions 24, 25 includes pads 32 (mounting pads) exposed on a surface of the printed circuit board 11, and the electronic component 12 is mountable on the pads 32. The pads 32 are also referred to as, for example, electrodes. The first component mounting portion 24 and the second component mounting portion 25 have the same structure and the same functions although the first component mounting portion 24 and the second component mounting portion 25 differ from each other in size and type of components to be mounted thereon. Accordingly, the first component mounting portion 24 is described in detail hereinafter as a representative mounting portion.

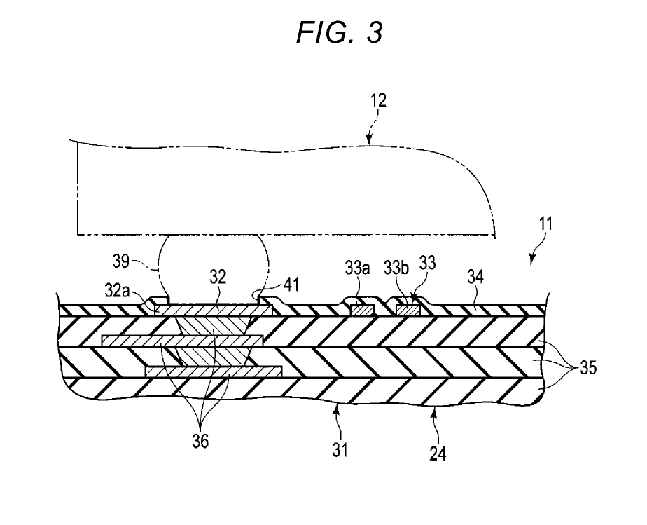

FIG. 3 shows a cross section of the first component mounting portion 24 (hereinafter “component mounting portion 24”). The component mounting portion 24 includes a substrate 31 (base member), the pads 32, a surface layer pattern 33, and a solder resist 34. The substrate 31 may include a plurality of insulating layers 35 (inner insulating layers) and wiring patterns 36 (inner layer patterns) mounted on these insulating layers 35. In the present embodiment, these component mounting portions 24, 25 also have flexibility.

The pads 32 are exposed on the surface of the substrate 31. That is, the pads 32 are exposed to the outside of the printed circuit board 11, and connecting portions 39 (solder balls, for example) of the electronic component 12 are connected to the pads 32. By connecting the connecting portions 39 to the pads 32, the electronic component 12 is mounted on the pads 32, and is electrically connected to the printed circuit board 11. The surface layer pattern 33 (conductor pattern, wiring pattern) includes a plurality of lines 33a, 33b, and is formed on a surface of the substrate 31. The plurality of lines 33a, 33b may be signal lines or power source lines.

As shown in FIG. 2 and FIG. 3, the solder resist 34 is formed on portions of the surface of the substrate 31 so as to avoid a portion corresponding to each pad 32 (the solder resist 34 is formed so as to avoid at least a center portion of each pad 32). The phrases “so as to avoid a portion corresponding to each pad 32” or “so as to avoid at least a center portion of each pad 32” means “at least the center portion of each pad is exposed to the outside” and includes, in its category, the case where a peripheral portion 32a of the bad 32 is covered by the solder resist 34 as shown in FIG. 3.

According to such a structure, the solder resist 34 includes opening portions 41 corresponding to the pads 32 (opening portions 41 for exposing the pads 32 to the outside). On the other hand, the solder resist 34 covers the surface layer pattern 33 (lines 33a, 33b).

The solder resist 34 is formed on the component mounting portion 24 so as to cover the whole region of the component mounting portion 24 except for the pads 32. The solder resist 34 is made of an insulation material so that the solder resist 34 electrically insulates the plurality of pads 32 from each other, and electrically insulates the plurality of lines 33a, 33b from each other. The solder resist 34 is provided so that a solder is not formed on portions other than contact portions for electric connection at the time of mounting the electronic component 12 on the printed circuit board 11 thus causing short-circuiting. The solder resist 34 also protects the printed circuit board 11 from an ambient environment such as dust, heat, or moisture, thus enhancing long-term reliability of the printed circuit board 11.

Next, a method of manufacturing the printed circuit board 11 according to the present embodiment is described.

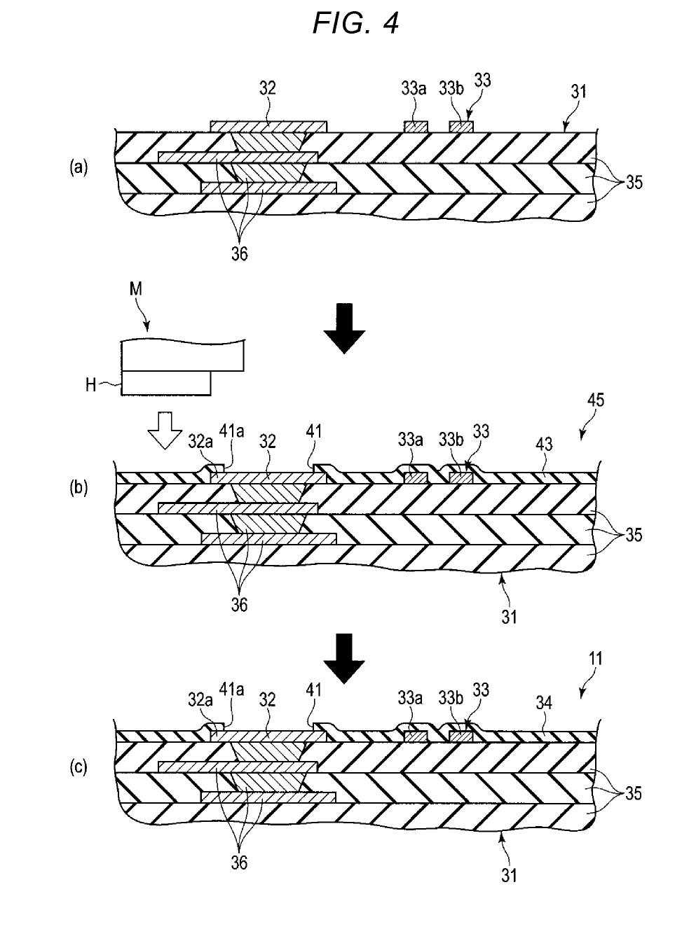

FIG. 4 shows one example of the method of manufacturing the printed circuit board 11. Steps up to a step of preparing the substrate 31 on which the pads 32 and the surface layer pattern 33 are formed are same as steps of a general method of manufacturing a printed circuit board, and hence the detailed explanation of the steps is omitted here.

As shown in FIG. 4, in one example of the method of manufacturing the printed circuit board 11, the substrate 31 having the pads 32 and the surface layer pattern 33 is prepared ((a) in FIG. 4). Next, the solder resist 34 is formed on the surface of the substrate 31 so as to avoid at least the center portion of each pad 32. In the present embodiment, the solder resist 34 is formed on the surface of the substrate 31 using an inkjet method (inkjet printing system).

To be more specific, first, pretreatment such as cleaning is carried out on the surface of the substrate 31. Next, a detection mark (alignment mark) formed on the individual substrate 31, for example, is read by a device, an expansion and contraction state (thermally expanded state) of the substrate 31 caused by an ambient environment is detected based on the position of the mark, and a position where a solder resist material is to be applied by coating is individually adjusted in accordance with the expansion and contraction state of the substrate 31.

Next, a solder resist material 43 having a fluidity (in a liquid state, for example) is applied on portions of the surface of the substrate 31 using an inkjet method such that the solder resist material 43 is not formed on at least the center portion of each pad 32. That is, the solder resist material 43 is discharged from an inkjet head H of the inkjet device M and is supplied to a position where the solder resist 34 is expected to be formed using an inkjet device M ((b) in FIG. 4). Subsequently, the primary curing of the coated solder resist material 43 is performed by applying UV light (ultraviolet rays) to the solder resist material 43. An intermediate 45 of a flexible printed circuit board is obtained by such primary curing of the solder resist material 43.

Next, heat is applied to the primarily-cured solder resist material 43 thus thermally curing the solder resist material 43 ((c) in FIG. 4). The solder resist 34 is formed by such thermal curing, and the printed circuit board 11 is manufactured.

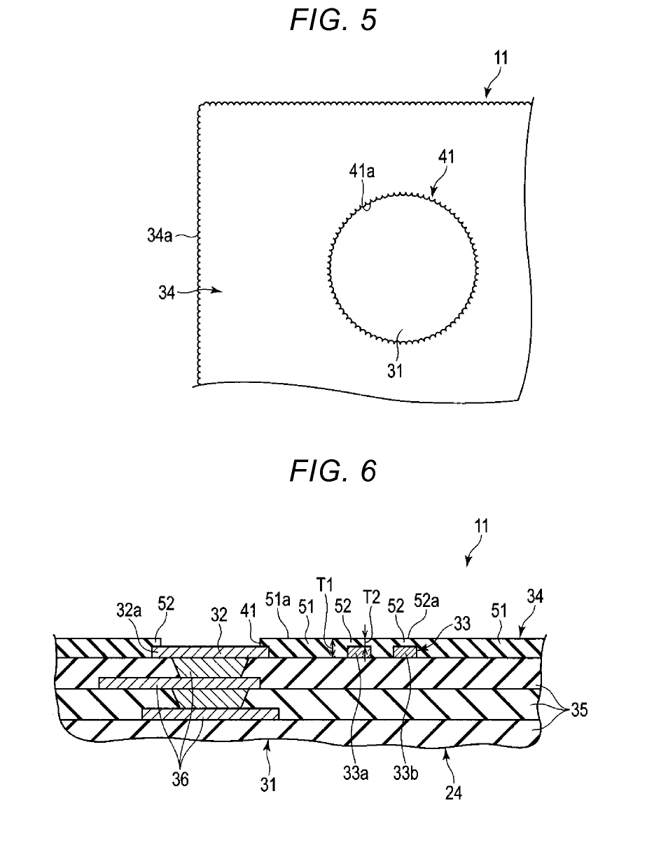

FIG. 5 shows one example of the solder resist 34 formed through the above-mentioned method. When the solder resist 34 is formed using an inkjet method, as shown in FIG. 5, there may be a case where an uneven shape corresponding to a shape of particle of sprayed ink remains at an edge portion 34a of the solder resist 34 and an inner peripheral edge 41a of each opening portion 41. The uneven shape does not always remain at such portions. For the sake of facilitating the explanation, FIG. 5 schematically shows the uneven shape in an enlarged manner relative to an actual uneven shape. Such an uneven shape may remain on the intermediate 45 of the flexible printed circuit board.

According to the above-mentioned method of forming a solder resist 34, various advantageous effects described hereinafter may be acquired. First, for a comparison purpose, a method of forming opening portions in the solder resist which correspond to pads by punching using a die is considered as a comparative method. In this case, when miniaturized electronic components which have been employed recently are mounted on a printed circuit board at a narrow pitch, the formation of such openings in extremely minute portions would be difficult when the punching of the die is employed.

Also, a method of forming a solder resist using a photosensitive material is considered as another comparative method. In this case, to form a solder resist, steps such as pretreatment, printing, drying, exposing, developing, peeling and thermal curing, and the like of a solder resist material would be necessary so that a manufacturing process would be long. Further, according to this method, even when a solder resist is formed on a surface of a substrate, first, the solder resist material is applied to the whole surface of the base member by screen printing or the like, and thereafter unnecessary solder resist portions are removed. Accordingly, an amount of the solder resist material which may be wasted is not small.

Further, according to the method of forming a solder resist using a photosensitive material, a scum (a residue of the solder resist material which cannot be removed in a peeling step) may remain on the pad and the remaining scum may adversely affect the formation of electroless Ni—Au plating and the soldering, which are succeeding steps. Accordingly a step of cleaning surfaces of the pads by plasma treatment or the like may be necessary after the above-mentioned peeling step.

Further, the flexible printed circuit board exhibits the larger expansion and contraction caused by change of the ambient temperature or the like, relative to a rigid wiring board. Accordingly, for example, when an exposure film is used, a size of the exposure film may not match a size of the flexible printed circuit board. Accordingly, accuracy of the positioning of the solder resist with respect to the pads may be affected by the expansion and contraction of the flexible printed circuit board.

On the other hand, according to the present embodiment, the solder resist 34 is formed as follows. That is, the solder resist material 43 is applied on portions of the surface of the substrate 31 on which the pads 32 are mounted using an inkjet method such that the solder resist material 43 is not formed on at least a center portion of each pad 32, and the solder resist material 43 is cured.

According to such a method, first, a process for forming the solder resist 34 may be largely shortened. That is, by adopting the inkjet method, the solder resist 34 may be formed through the steps including pretreatment, coating using an inkjet method, UV-curing, and thermal curing. Such a method can be performed in a shorter time period than a method of forming a solder resist which necessitates steps such as exposing, developing, and a peeling. Accordingly, it is possible to reduce a material cost and a labor cost.

Further, according to the method of forming a solder resist using an inkjet method, the solder resist material 43 is applied only to necessary portions on the surface of the substrate 31. Accordingly, compared to a method where a solder resist material is applied to the whole surface of the substrate 31, amount of wasted solder resist material is small. Accordingly, it is possible to efficiently use the solder resist material.

According to the method of forming a solder resist using an inkjet method, the solder resist material 43 is applied by only to necessary portions, so that a scum or the like does not remain on the pads 32. As a result, even when any particular post-treatment is not performed, the formation of electroless Ni—Au plating and soldering may be favorably performed. Accordingly, reliability of the printed circuit board 11 may be improved while shortening the manufacturing process.

With respect to the positional accuracy of the solder resist 34 with respect to the pads 32, by adopting the inkjet method, the position where the solder resist material 43 is applied may be adjusted so as to conform to positions of the pads 32 on the individual printed circuit boards 11. That is, for example, an amount of expansion and contraction of the individual printed circuit board 11 is detected using a detection mark or the like, and the position where the solder resist material 43 is applied may be individually adjusted based on the amount of expansion and contraction of the printed circuit board 11. Accordingly, the positional accuracy of the solder resist 34 with respect to the pads 32 may be acquired more easily compared to the case where an exposure film is used. In other words, according to the method of forming the solder resist using an inkjet method, the positional accuracy of the solder resist is minimally affected by the expansion and contraction of the flexible printed circuit board caused by changes of an ambient temperature.

According to the method of forming the solder resist using an inkjet method, an exposure mask and a printing plate are unnecessary. Accordingly, a material cost may be reduced. Further, the method may easily achieve the production of many kinds in small quantities.

Next, the second to seventh embodiments are described. According to the second to seventh embodiments, the shape and the structure of the solder resist 34 are modified from the ones according to the first embodiment, considering the advantageous effects acquired by forming the solder resist 34 by an inkjet method. The structural components of the second to seventh embodiments which have functions identical with or similar to the structural components of the first embodiment are depicted with the same symbols, and the repeated explanation of these structural components is omitted. The structures of the second to seventh embodiments other than the structures described hereinafter are same as the corresponding structures of the first embodiment.

### Second Embodiment

FIG. 6 shows a printed circuit board 11 according to the second embodiment. In the second embodiment, considering the advantageous effect acquired by using an inkjet method, a thickness of a solder resist 34 is partially changed.

To describe the present embodiment in detail, the solder resist 34 has first portions 51 and second portions 52. The first portions 51 are formed in regions which do not correspond to surface layer patterns 33 in the thickness direction of a substrate 31, and are in contact with portions of a surface of the substrate 31 where the surface layer patterns 33 are not formed. The second portions 52 are formed in regions which correspond to the surface layer patterns 33 in the thickness direction of the substrate 31, and overlap peripheral portions 32a of pads 32 or lines 33a, 33b.

As shown in FIG. 6, in the present embodiment, a thickness of the first portion 51 of the solder resist 34 and a thickness of the second portion 52 of the solder resist 34 are different from each other, such that a surface 51a of the first portion 51 and a surface 52a of the second portion 52 are positioned on substantially the same plane. That is, the thickness T1 of the first portion 51 is larger than the thickness T2 of the second portion 52 by an amount equal to a thickness of the pad 32 or a thickness of the lines 33a, 33b.

By adopting the inkjet method, a coating amount of the solder resist material 43 may be changed depending on positions. Accordingly, the presence or the non-presence of the surface layer pattern 33 is first determined, and then a coating amount of the solder resist material 43 is increased at portions (first portions 51) where the surface layer pattern 33 is not present and the coating amount of the solder resist material 43 is decreased at portions (second portions 52) where the surface layer pattern 33 is present. According to such distribution of the thickness, a surface of the whole solder resist 34 may become smooth.

It may be also possible to acquire a solder resist having a smooth surface by laminating an insulating raw film material on a surface of a substrate, for example. However, such a raw film material is generally expensive, and hence a manufacturing cost of a printed circuit board may be high. On the other hand, when the solder resist 34 is formed using an inkjet method as in the case of the present embodiment, the solder resist 34 having a smooth surface may be formed without using an expensive raw film material.

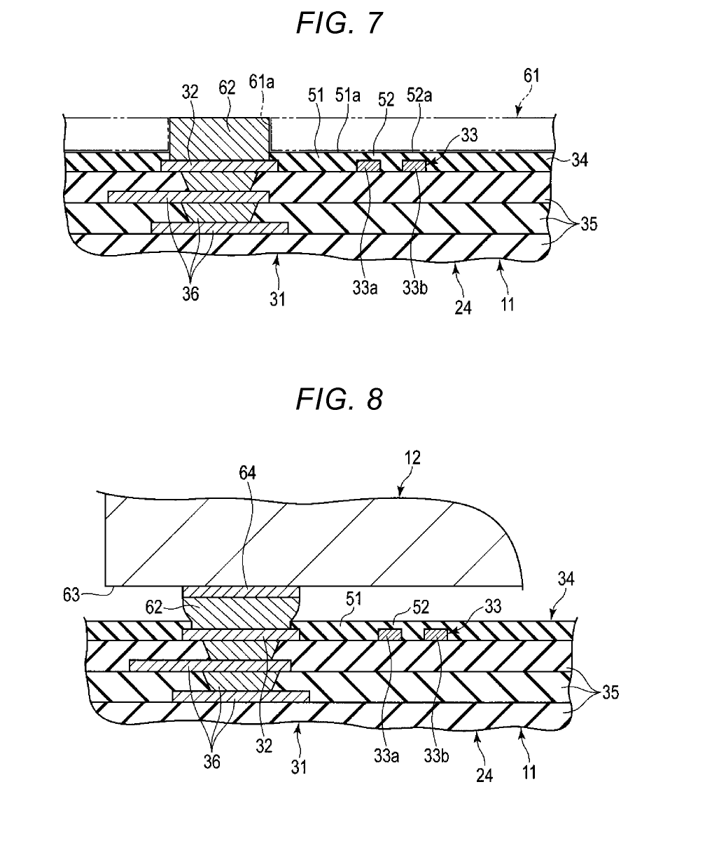

FIG. 7 shows a step of coating a cream solder 62 on the printed circuit board 11 shown in FIG. 6. As shown in FIG. 7, for example, when the cream solder 62 is applied to the printed circuit board 11 by a screen printing, a mask 61 having opening portions 61a corresponding to the pads 32 is placed on the solder resist 34. Provided that a surface of the solder resist 34 is smooth as in the case of the present embodiment, a gap is not likely to be generated between surfaces of the solder resist 34 and the mask 61. Accordingly, the cream solder 62 may be applied with high accuracy such that there is few irregularities in an amount of cream solder 62 applied to the individual pads 32. Accordingly, a mounting yield may be improved.

FIG. 8 shows the printed circuit board 11 in a state where an electronic component 12 is mounted on the printed circuit board 11. The electronic component 12 has a lower surface 63 which faces the printed circuit board 11 and connecting portions 64 (electric connecting portions) formed on the lower surface 63. One example of the electronic component 12 is an LGA (Land Grid Array) component on which the connecting portions 64 configuring lands are formed. The electronic component 12 may be a BGA (Ball Grid Array) component on which solder balls are formed as the connecting portions 64.

### Third Embodiment

FIG. 9 shows a printed circuit board 11 according to the third embodiment. In the third embodiment, a thickness of a solder resist 34 is partially changed so as to utilize the advantageous effects of using an inkjet method.

To describe the present embodiment in detail, a surface layer pattern 33 of the printed circuit board 11 includes first lines 71a, 71b, 71c and second lines 72a, 72b. The first lines 71a, 71b, 71c configure general signal lines or power source lines, for example. The second lines 72a, 72b configure signal lines through which high-speed signals (signals having higher frequency) flow compared to the first lines 71a, 71b, 71c. One example of the second lines 72a, 72b is microstrip lines which configure high-speed transmission lines. The second lines 72a, 72b may be signal lines through which high-speed signals conforming to the PCI Express standard flow, or other signal lines, for example.

As shown in FIG. 9, the solder resist 34 according to the present embodiment has first portions 73 (first regions) and second portions 74 (second regions). The first portion 73 covers the first lines 71a, 71b, 71c and an area around the first lines 71a, 71b, 71c. The second portion 74 covers the second lines 72a, 72b and an area around the second lines 72a, 72b. A thickness T4 of the second portion 74 is smaller than a thickness T3 of the first portion 73. Due to such a structure, the second lines 72a, 72b are disposed closer to an ambient environment (for example, air layer) compared to the first lines 71a, 71b, 71c.

According to the above-mentioned structure, the present embodiment may achieve various advantageous effects substantially equal to the advantageous effects of the first embodiment and, at the same time, a transmission speed of the printed circuit board 11 may be improved and a transfer loss may be reduced. According to the studies carried out by the inventors of the present disclosure, it is found that, with respect to signal line through which high-speed signals flows, the lower an effective dielectric constant, the more electric characteristics of the high-speed signals is improved. Accordingly, the signal lines having a low effective dielectric constant are advantageous in view of improving a transmission speed and reducing a transfer loss. According to the studies carried out by the inventors of the present disclosure, it is also found that when a solder resist is formed on the signal lines, an effective dielectric constant of the signal lines is increased.

In view of the above, in the present embodiment, the thickness of the first portion 73 of the solder resist 34 and the thickness of the second portion 74 of the solder resist 34 are different from each other. That is, the first portion 73 of the solder resist 34 which covers the first lines 71a, 71b, 71c is formed with a normal thickness, for example, and the second portion 74 of the solder resist 34 which covers the second lines 72a, 72b is formed with a thickness smaller than the thickness of the first portion 71. Due to such a structure, an influence of an ambient environment (air layer) on the second lines 72a, 72b is increased, and hence an effective dielectric constant of the second lines 72a, 72b may be lowered. Accordingly, an electric characteristic of the second lines 72a, 72b is improved so that a transmission speed of the printed circuit board 11 may be improved, and a transfer loss may be reduced.

### Fourth Embodiment

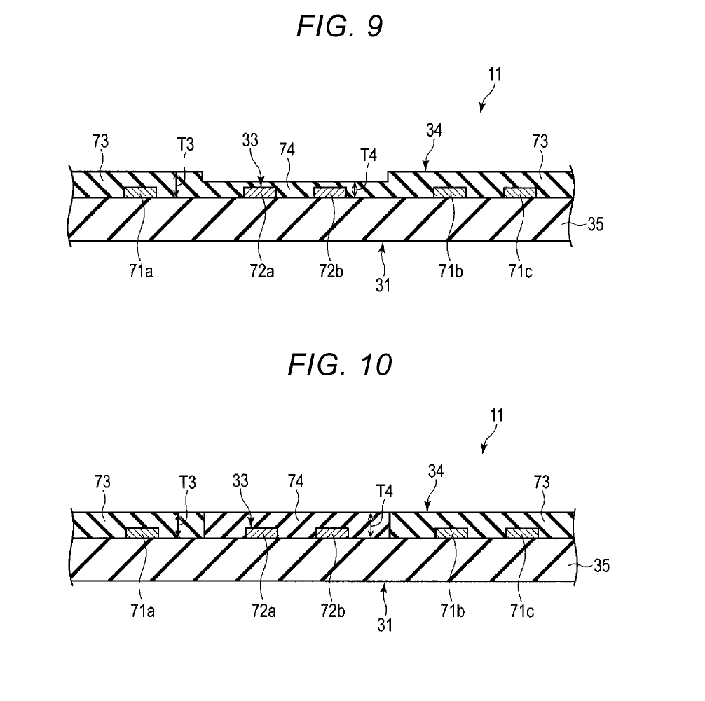

FIG. 10 shows a printed circuit board 11 according to the fourth embodiment. In the fourth embodiment, to utilize an advantageous effect of an inkjet method, a portion of the solder resist 34 is made of a material different from a material of the other portions of the solder resist 34.

To describe the present embodiment in detail, a surface layer pattern 33 of the printed circuit board 11 includes first lines 71a, 71b, 71c, and second lines 72a, 72b. The details of the first lines 71a, 71b, 71c and the second lines 72a, 72b are substantially the same as the corresponding lines in the third embodiment.

As shown in FIG. 10, the solder resist 34 according to the present embodiment has first portions 73 (first regions) and second portions 74 (second regions). The first portion 73 covers the first lines 71a, 71b, 71c and an area around the first lines 71a, 71b, 71c. The second portion 74 covers the second lines 72a, 72b and an area around the second lines 72a, 72b. The second portion 74 is made of a material having a lower dielectric constant than a material of the first portion 73. A thickness T4 of the second portion 74 may be substantially equal to a thickness T3 of the first portion 73, or may be different from the thickness T3 of the first portion 73.

According to the above-mentioned structure, the fourth embodiment may achieve various advantageous effects substantially the same as the advantageous effects of the first and second embodiments. At the same time, in the same manner as the third embodiment, a transmission speed of the printed circuit board 11 may be improved, and a transfer loss may be reduced. That is, in the present embodiment, the first portion 73 of the solder resist 34 and the second portion 74 of the solder resist 34 are formed using different materials (different kinds of materials). That is, the first portion 73 of the solder resist 34 which covers the first lines 71a, 71b, 71c is formed using a first material, while the second portion 74 of the solder resist 34 which covers the second lines 72a, 72b is formed using a second material having a smaller dielectric constant than the first material, by changing a solder resist material to be applied. According to such a structure, an effective dielectric constant of the second lines 72a, 72b may be lowered. Accordingly, an electric characteristic of the second lines 72a, 72b is improved so that a transmission speed of the printed circuit board 11 is improved and a transfer loss is reduced.

A material having a small dielectric constant is expensive in general. That is, according to the present embodiment, an expensive material is used only for forming portions where the use of the expensive material is effective in view of a transmission speed. Accordingly, a transmission speed of the printed circuit board 11 may be improved and a transfer loss may be reduced while suppressing the amount of the expensive material as a whole.

### Fifth Embodiment

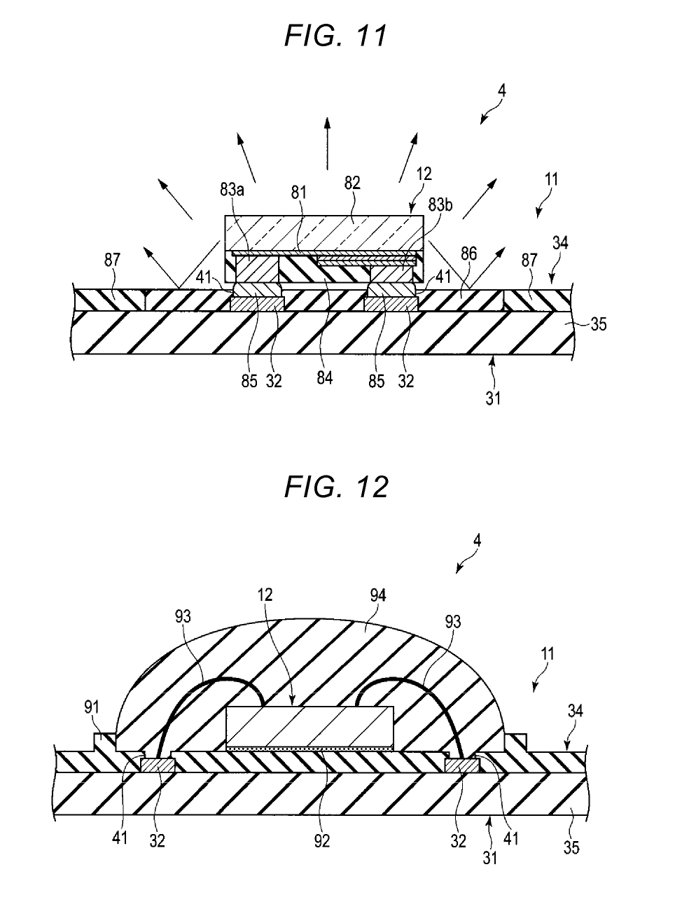

FIG. 11 shows a module 4 according to the fifth embodiment. In the fifth embodiment, to utilize an advantageous effect of an inkjet method, a portion of the solder resist 34 is made of a material different from a material of the other portions of the solder resist 34.

To describe the present embodiment in detail, an electronic component 12 according to the present embodiment is a light emitting component, for example, and includes a light emitting element 81 (semiconductor element), a light-transmissive portion 82, electrodes 83a, 83b, and a mold resin 84. The light emitting element 81 includes a plurality of clad layers and active layers interposed between these clad layers, respectively. The light emitting element 81 includes an InGaN layer which emits blue light, for example.

The light transmissive portion 82 covers the light emitting element 81. One example of the light transmissive portion 82 is a phosphor layer, and the phosphor layer is made of a resin where phosphor particles which convert blue light into long-wavelength light are dispersed. The light transmissive portion 82 may be formed of a colorless transparent layer or the like.

The electrodes 83a, 83b are posts made of metal (copper, for example) and project from the light emitting element 81. The electrodes 83a, 83b are connected to pads 32 of the printed circuit board 11 with a bonding material 85 such as solder (cream solder). The electrodes 83a, 83b supply electricity to the light emitting element 81. The mold resin 84 covers peripheral surfaces of the electrodes 83a, 83b.

As shown in FIG. 11, a solder resist 34 according to the present embodiment has first portions 86 (first regions) and second portions 87 (second regions). The first portion 86 is formed around the pads 32 on which the light emitting element 81 is mounted. The first portion 86 is formed at a position which receives light from the electronic component 12, for example. The first portion 86 is formed using a material having a color of high light reflectance such as white.

The second portion 87 is formed outside the first portion 86, and is located away from the light emitting element 81 than the first portion 86 is. The second portion 87 is formed of an inexpensive material having low light reflectance compared to a material of the first portion 86.

According to the above-mentioned structure, the fifth embodiment may achieve various advantageous effects substantially equal to the advantageous effects of the first and second embodiments and, at the same time, the fifth embodiment may provide a module 4 where irradiation efficiency of the electronic component 12 is improved. That is, in the present embodiment, the first portion 86 of the solder resist 34 and the second portion 87 are formed using different materials (different kinds of materials). In other words, the first portion 86 of the solder resist 34 positioned around the electronic component 12 is formed using a first material having relatively high light reflectance, while the second portion 87 which receives a smaller amount of light from the electronic component 12 compared to the first portion 86 is formed using a material having lower light reflectance than the first portion 86. According to such a structure, the fifth embodiment may provide the module 4 where irradiation efficiency of the electronic component 12 is improved.

A material having a color, such as white, of high light reflectance, for example, is generally expensive. That is, according to the present embodiment, an expensive material is used only for portions that contribute to improve irradiation efficiency. Accordingly, the fifth embodiment may provide the module 4 where irradiation efficiency is improved while suppressing an amount of an expensive material as a whole.

### Sixth Embodiment

FIG. 12 shows a module 4 according to the sixth embodiment. In the sixth embodiment, to utilize an advantageous effect of an inkjet method, projecting portions 91 (projections, weir portions, support portions, restricting portions) are formed on a solder resist 34.

To describe the present embodiment in detail, the module 4 according to the present embodiment includes an electronic component 12. The electronic component 12 is fixed to a surface of the solder resist 34 with an adhesive portion 92. The adhesive portion 92 is formed of an adhesive sheet or an adhesive agent, for example. Bonding wires 93 are provided between the electronic component 12 and the pads 32. The electronic component 12 is electrically connected to the pads 32 through the bonding wires 93. The electronic component 12 may be connected to pads 32 of a printed circuit board 11 by soldering.

As shown in FIG. 12, the module 4 includes an insulating resin portion 94 which covers the electronic component 12. The resin portion 94 is made of a potting resin, for example, and integrally seals the electronic component 12 and the plurality of bonding wires 93. The resin portion 94 is formed such that a resin material in a fluid state is supplied to a surface of the printed circuit board 11, and the resin material is cured.

As shown in FIG. 12, the solder resist 34 according to the present embodiment includes the projecting portions 91. The projecting portions 91 are formed by increasing a thickness of portions of the solder resist 34 by partially increasing a coating amount of the solder resist material 43. The projecting portion 91 is formed in a frame shape so as to surround the electronic component 12 and the pads 32. The projecting portion 91 functions as a weir which restricts the flow of a resin material having fluidity. That is, the resin portion 94 is formed inside the projecting portion 91, and is supported by the projecting portion 91, and hence it is possible to prevent the resin portion 94 from spreading out of a predetermined area.

According to the above-mentioned structure, the sixth embodiment may achieve various advantageous effects substantially equal to the advantageous effects of the first embodiment and, at the same time, the sixth embodiment may improve packing density of the printed circuit board 11 while maintaining reliability of the printed circuit board 11. That is, the projecting portions 91 which block a resin material for forming the resin portions 94 are formed by making portions of the solder resist 34 have a larger thickness. Accordingly, even when an amount of resin material sufficient to cover the electronic component 12 and the bonding wires 93 is supplied, it is possible to retain the resin material within an area surrounded by the projecting portion 91. Accordingly, areas on the surface of the printed circuit board 11 which are occupied by the resin portions 94 may be decreased. According to such a structure, the sixth embodiment may improve packing density of the printed circuit board 11 while improve reliability of the printed circuit board 11.

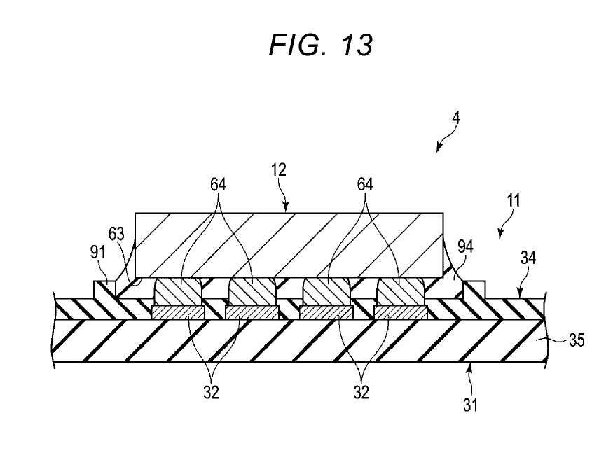

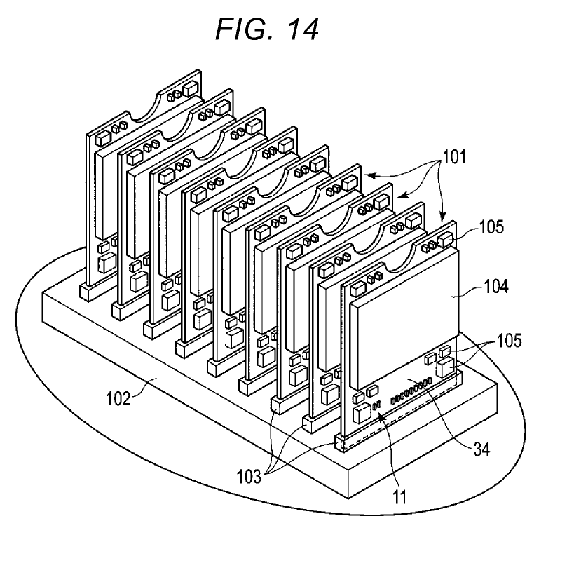

FIG. 13 shows a module 4 according to one modification example of the present embodiment. In this modification example, an electronic component 12 includes a lower surface 63 which faces a printed circuit board 11 and a plurality of connecting portions 64 (solder connecting portions, solder balls, for example) formed on the lower surface 63. The module 4 includes a resin portion 94 between the lower surface 63 of the electronic component 12 and the printed circuit board 11. The resin portion 94 is made of an underfill, for example. The resin portion 94 surrounds the plurality of connecting portions 64, and enters spaces defined between the connecting portions 64 so as to insulate the plurality of connecting portions 64 from each other. As in the case of this modification example, a projecting portion 91 of a solder resist 34 is not limited to a portion which dams up a resin material for forming a potting resin, and may be a portion which dams up a resin material made of an underfill or other resin materials.

### Seventh Embodiment

FIG. 14 shows semiconductor devices 101 according to the seventh embodiment. The semiconductor device 101 is one example of “semiconductor module” and “semiconductor memory device.” Although the semiconductor device 101 is an SSD (Solid State Drive), the semiconductor device 101 is not limited to the SSD.

The semiconductor devices 101 may be used in a state where the semiconductor devices 101 are mounted on a host device 102 such as a server, for example. The host device 102 includes a plurality of connectors 103 (slots, for example). The plurality of semiconductor devices 101 are mounted on the connectors 103 of the host device 102, respectively. The semiconductor device 101 includes a printed circuit board 11, a semiconductor package 104 mounted on the printed circuit board 11, and a plurality of electronic components 105 mounted on the printed circuit board 11. The semiconductor package 104 includes a plurality of semiconductor elements and a mold resin which integrally covers these semiconductor elements, for example.

The printed circuit board 11 includes a plurality of pads 32 on which the semiconductor package 104 and the electronic component 105 are mounted and a solder resist 34 which is formed such that at least center portions of the respective pads 32 is exposed. The solder resist 34 is formed using an inkjet method, and has the same structure as the solder resist according to any one of the first to sixth embodiments. The semiconductor device 101 having such a structure may also achieve various advantageous effects substantially equal to the advantageous effects of the first to sixth embodiments.

Although the first to seventh embodiments are described heretofore, the embodiments are not limited to the above-mentioned examples. For example, the above-mentioned respective embodiments are also applicable to a method of forming a solder resist of a rigid printed circuit board.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a flexible printed circuit module, comprising:
discharging an insulating material from an inkjet head towards a surface of a flexible printed circuit board, such that an electrode on the surface of the flexible printed circuit board is exposed; and
curing the insulating material to be formed.

2. The method according to claim 1, wherein
the curing includes irradiating the insulating material on the surface of the flexible printed circuit with a UV ray, and then heating the insulating material.

3. The method according to claim 1, further comprising:
determining an amount of expansion or contraction of the flexible printed circuit board with respect to a default state; and
determining a target region on the surface of the flexible printed circuit board based on the determined amount, wherein
the insulating material is discharged towards the target region.

4. The method according to claim 1, wherein
the insulating material is discharged so as to cover an edge portion of the electrode and not cover a center portion of the electrode.

5. The method according to claim 4, wherein
a thickness of the insulating material formed on the edge portion of the electrode is smaller than a thickness of the insulating material directly formed on the flexible printed circuit board.

6. The method according to claim 5, wherein a surface of the insulating material is flat.

7. The method according to claim 4, wherein
the insulating material is discharged so as to cover one or more wirings on the surface of the flexible printed circuit board.

8. The method according to claim 7, wherein
the one or more wirings include a first wiring and a second wiring, and
a thickness of the insulating material on the first wiring is smaller than a thickness of the insulating material on the second wiring.

9. The method according to claim 4, wherein
the flexible printed circuit board includes a predetermined region including the electrode, and
the insulating material on the flexible printed circuit board includes a protruding region that surrounds the predetermined region.

10. The method according to claim 9, further comprising:
attaching an electronic unit in the predetermined region of the flexible printed circuit board; and
applying a resin material in the predetermined region of the flexible printed circuit board, so as to cover the electronic unit.

11. The method according to claim 9, further comprising:
attaching an electronic unit in the predetermined region of the flexible printed circuit board and above the electrode; and
applying a resin material in the predetermined region of the flexible printed circuit board and below the electronic unit.

12. The method according to claim 1, further comprising:
attaching an electronic unit on the flexible printed circuit board, such that the electronic unit is electrically connected to the electrode.

13. A method for manufacturing a flexible printed circuit module, comprising:
discharging a first insulating material from an inkjet head towards a first target region of a flexible printed circuit board;
discharging a second insulating material that is different from the first insulating material from an inkjet head towards a second target region of the flexible printed circuit board that is adjacent to the first target region; and
curing the first and second insulating materials to be formed.

14. The method according to claim 13, wherein
the curing includes irradiating the first and second insulating materials on the surface of the flexible printed circuit with a UV ray, and then heating the first and second insulating materials.

15. The method according to claim 13, wherein
the first and second target regions of the flexible printed circuit board both include a wiring, and
the first and second insulating materials are formed on the wirings.

16. The method according to claim 15, wherein
a dielectric constant of the first insulating material is different from a dielectric constant of the second insulating material.

17. The method according to claim 12, wherein
the first target region of the flexible printed circuit board includes an electrode, and
the first insulating material is discharged such that the electrode is exposed.

18. The method according to claim 17, further comprising:
attaching an light emitting unit on the first insulating material, such that the light emitting unit is electrically connected to the electrode, and
a reflectance of the first insulating material is greater than a reflectance of the second insulating material.

19. The method according to claim 18, wherein the first insulating material is white.
